(19) United States
(12) Patent Application Publication
(10) Pub. No.: US 2015/0115436 A1
(43) Pub. Date: Apr. 30, 2015

(54) SEMICONDUCTOR DEVICE AND METHOD OF MANUFACTURING THE SAME

(71) Applicant: SAMSUNG ELECTRONICS CO., LTD., Suwon-si (KR)

(72) Inventors: Jun-Won HAN, Seoul (KR); Hye-Reun KIM, Yongin-si (KR); Hoon HAN, Anyang-si (KR); Dong-Jun LEE, Seoul (KR); Jung-Sik CHOI, Seongnam-si (KR)

(21) Appl. No.: 14/308,837

(22) Filed: Jun. 19, 2014

(30) Foreign Application Priority Data
Oct. 28, 2013 (KR) 10-2013-0128352

(51) Int. Cl. H01L 23/538; H01L 21/768; H01L 23/00

(52) U.S. Cl. CPC H01L 23/5384; H01L 24/11; H01L 24/81; H01L 24/16; H01L 21/76898; H01L 21/76843; H01L 21/7684
USPC 257/737; 438/614; 438/107

(57) ABSTRACT

Provided is a method of manufacturing a semiconductor device, the method including forming a via structure through a portion of a substrate; partially removing the substrate to expose a portion of the via structure; forming a protecting layer on the substrate to cover the portion of the via structure exposed by partially removing the substrate, the protecting layer including a photosensitive organic insulating material; curing the protecting layer to form a cured protecting layer; planarizing the cured protecting layer until a part of the via structure is exposed; and forming a pad structure to contact the part of the via structure exposed by planarizing the cured protecting layer.

### CROSS-REFERENCE TO RELATED APPLICATION

Korean Patent Application No. 10-2013-0128352, filed on Oct. 28, 2013, in the Korean Intellectual Property Office, and entitled: “Semiconductor Device and Method of Manufacturing the Same,” is incorporated by reference herein in its entirety.

### BACKGROUND

1. Field

Example embodiments relate to a semiconductor and a method of manufacturing the same. More particularly, example embodiments relate to a semiconductor device including a via structure and a method of manufacturing the same.

2. Description of the Related Art

To manufacture a highly integrated semiconductor device having a high capacity, a plurality of semiconductor chips may be stacked to form a package structure. When a package structure is formed, a via structure may be formed through a substrate on which circuit patterns are formed, a pad structure may be formed on the substrate to contact the via structure, and a plurality of semiconductor chips may be stacked to be connected to each other.

### SUMMARY

Embodiments may be realized by providing a method of manufacturing a semiconductor device, the method including forming a via structure through a portion of a substrate; partially removing the substrate to expose a portion of the via structure; forming a protecting layer on the substrate to cover the portion of the via structure exposed by partially removing the substrate, the protecting layer including a photosensitive organic insulating material; curing the protecting layer to form a cured protecting layer; planarizing the cured protecting layer until a part of the via structure is exposed; and forming a pad structure to contact the part of the via structure exposed by planarizing the cured protecting layer.

Forming the protecting layer on the substrate may include coating a compound including a thermosetting organic polymer and a photosensitive material on the substrate to form a preliminary protecting layer; and soft-baking the substrate on which the preliminary protecting layer is formed.

The preliminary protecting layer may further include a cross linking agent and a curing catalyst.

The method may further include, prior to curing the protecting layer, forming a trench for forming an alignment pattern at an upper portion of the protecting layer.

Forming the trench may include irradiating a light on a portion of the protecting layer using an exposure mask; and developing the portion of the protecting layer irradiated with the light.

Forming the via structure may include partially removing the substrate to form a recess; forming an insulating layer on an inner wall of the recess and on the substrate; forming a barrier layer on the insulating layer, the forming of the insulating layer and the barrier layer partially filling the recess; forming a first conductive layer on the barrier layer to fill a remaining portion of the recess; and planarizing the first conductive layer, the barrier layer and the insulating layer until a top surface of the substrate is exposed to form an insulating layer pattern, a barrier layer pattern and a first conductive layer pattern sequentially stacked in the recess.

The cured protecting layer may be planarized until the first conductive layer pattern is exposed.

The method may further include, prior to forming the pad structure, forming a seed layer on the portion of the via structure exposed by planarizing the cured protecting layer and on the protecting layer; and forming a photoresist pattern on the seed layer, the photoresist patter having an opening exposing a portion of the seed layer overlapping the via structure. Forming the pad structure may include forming a second conductive layer to fill the opening; removing the photoresist pattern to expose a part of the seed layer; and removing the part of the seed layer exposed by removing the photoresist pattern.

Forming the second conductive layer may include performing a plating process.

The method may further include, prior to forming the via structure, forming a circuit pattern on the substrate; and forming an insulating interlayer on the substrate to cover the circuit pattern. The via structure may be formed through the insulating interlayer.

The method may further include, after forming the pad structure, stacking a semiconductor chip on the pad structure to be electrically connected thereto.

Embodiments may be realized by providing a semiconductor device, including a via structure in a substrate, a portion of the via structure being exposed to an outside of the substrate; a protecting layer surrounding a sidewall of the portion of the via structure exposed to the outside of the substrate, the protecting layer including a thermosetting organic polymer and a photosensitive material; and a pad structure contacting a top surface of the portion of the via structure exposed to the outside of the substrate.

The protecting layer may include an alignment pattern.

The via structure may include a first conductive layer pattern and a barrier layer pattern surrounding a sidewall of the first conductive layer pattern, and the pad structure may contact at least a portion of the first conductive layer pattern.

The pad structure may include a seed layer pattern and a second conductive layer pattern sequentially stacked.

Embodiments may be realized by providing a method of manufacturing a semiconductor device, including removing a portion of a substrate to expose a portion of a via structure in the substrate; and coating a protecting layer directly on the substrate to cover the portion of the via structure exposed by removing a portion the substrate, the protecting layer including a thermosetting organic polymer and a photosensitive material.

The method may further include forming an alignment pattern in the protecting layer without forming a photoresist pattern on the protecting layer.

Forming the alignment pattern in the protecting layer may include irradiating a light on a portion of the protecting layer that does not overlap the via structure; and developing the protecting layer such that the portion of the protecting layer irradiated by the light dissolves.

The method may further include curing the protecting layer to form a cured protecting layer; planarizing the cured protecting layer to expose a part of the via structure; and forming a pad structure to contact the part of the via structure exposed by planarizing the cured protecting layer. The protecting layer may be formed as a single layer.

The photosensitive material may be dissolved in a solvent to form a compound, which is coated on the substrate by spin on coating; and the thermosetting organic polymer may selected from polyimide, novolac, polybenzoxazole, benzocyclobutene, silicon polymer, epoxy polymer, or acrylate polymer.

### BRIEF DESCRIPTION OF THE DRAWINGS

Features will become apparent to those of skill in the art by describing in detail exemplary embodiments with reference to the attached drawings in which:

FIG. 1 illustrates a cross-sectional view depicting a semiconductor device in accordance with example embodiments;

FIGS. 2 to 12 illustrate cross-sectional views depicting stages of a method of manufacturing a semiconductor device in accordance with example embodiments; and

FIG. 13 illustrates a cross-sectional view depicting stage of a method of manufacturing a stacked semiconductor device in accordance with example embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. In addition, it will also be understood that when a layer is referred to as being “between” two layers, it can be the only layer between the two layers, or one or more intervening layers may also be present. Like numerals refer to like elements throughout. As used herein, the term “and/or” includes any and all combinations of one or more of the associated listed items.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to be limiting.

Unless otherwise defined, all terms (including technical and scientific terms) used herein have the same meaning as commonly understood by one of skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

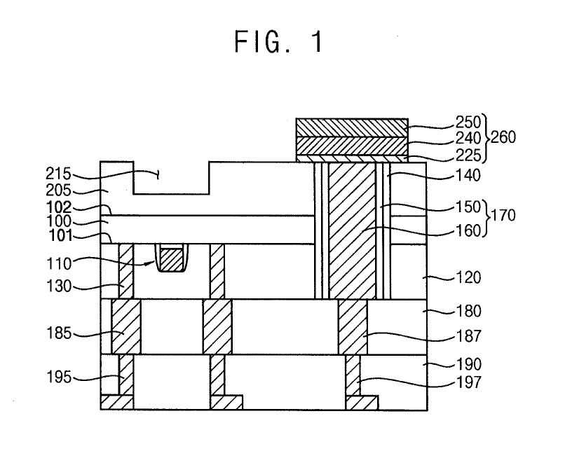

FIG. 1 illustrates a cross-sectional view depicting a semiconductor device in accordance with example embodiments.

Referring to FIG. 1, the semiconductor device may include a substrate 100, a via structure 170, a protecting layer 205 and a pad structure 260.

The substrate 100 may be, e.g., a silicon substrate, a germanium substrate, a silicon-germanium substrate, a silicon-on-insulator (SOI) substrate, or a germanium-on-insulator (GOI) substrate.

A circuit pattern 110 and a first insulating interlayer 120 covering the circuit pattern 110 may be formed on a first surface 101 of the substrate 100. The circuit pattern 110 may include, e.g., a transistor or a diode. A transistor is shown as the circuit pattern 110 in FIG. 1. A gate structure including a gate insulating layer pattern and a gate electrode may be formed on the first surface 101 of the substrate 100, an impurity region (not shown) may be formed at a portion of the first surface 101 of the substrate 100 adjacent to the gate structure. The first insulating interlayer 120 may include an oxide, e.g., borophosphosilicate glass (BPSG), undoped silicate glass (USG), or spin on glass (SOG).

A contact plug 130 may be formed through the first insulating interlayer 120 to contact the impurity region. Accordingly, the contact plug 130 may be electrically connected to the circuit pattern 110. The contact plug 130 may include a conductive material, e.g., a metal and/or polysilicon doped with impurities.

A second insulating interlayer 180 having first and second wirings 185 and 187 therethrough may be formed on the first insulating interlayer 120, and a third insulating interlayer 190 having third and forth wirings 195 and 197 therethrough may be formed on the second insulating interlayer 180. The first and second wirings 185 and 187 may contact at least portions of the contact plug 130 and a first conductive layer pattern 160 of the via structure 170, respectively. The wirings 185 and 195, the contact plug 130 and the circuit pattern 110 may be electrically connected to each other, and the wirings 187 and 197 and the via structure 170 may be electrically connected to each other.

In FIG. 1, the second and third insulating interlayers 180 and 190 and the first to fourth wirings 185, 187, 185 and 197 are shown; however, more insulating interlayers and more wirings may be further formed.

The via structure 170 may be formed through the substrate 100 and the first insulating interlayer 120. A portion of the via structure 170 may be exposed to an outside of the substrate 100, and a sidewall of the exposed portion of the via structure 170 may be surrounded with the protecting layer 205. The via structure 170 may include the first conductive layer pattern 160 and a barrier layer pattern 150 surrounding a sidewall thereof, and an insulating layer pattern 140 may surround a sidewall of the via structure 170. The first conductive layer pattern 160 may include a metal, e.g., copper (Cu) or tungsten (W). The barrier layer pattern 150 may include a metal or a metal nitride, e.g., tantalum (Ta), tantalum nitride (TaN), titanium (Ti), titanium nitride (TiN), ruthenium (Ru), cobalt (Co), nickel (Ni), nickel boride (NiB), or tungsten nitride (WN). The insulating layer pattern 140 may include an insulating material, e.g., silicon oxide or silicon nitride.

The protecting layer 205 may be formed on a second surface 102 of the substrate 100, on which the circuit pattern 110 is not formed, to contact the insulating layer pattern 140 and surround the sidewall of the exposed portion of the via structure 170. The protecting layer 205 may include an alignment pattern 215 used for manufacturing a stacked semiconductor device and/or a package structure including the same.

The protecting layer 205 may be a photosensitive organic insulating layer. The protecting layer 205 may include a thermosetting organic polymer and a photosensitive material. The thermosetting organic polymer may be a thermosetting resin having an insulating characteristic, e.g., polyimide, novolac, polybenzoxazole, benzocyclobutene, silicon polymer, epoxy polymer, or acrylate polymer. The photosensitive material may be a positive photosensitive material.

The protecting layer 205 may further include a cross linking agent and a curing catalyst. The cross linking agent may cross link the thermosetting organic polymer, and may include, e.g., formalin, formalin-alcohol, melamine resin, urea resin, a phenolic compound including at least two methylols or at least two alkoxymethylols, and/or an epoxy compound including at least two epoxy functional groups. The curing catalyst may cause a curing reaction of the thermosetting organic polymer, and may include, e.g., acid anhydride.

In example embodiments, the protecting layer 205 may further include a photoacid generator (PAG), which may be any compound generating acid by light.

The pad structure 260 may be formed on the protecting layer 205 to contact a top surface of the exposed portion of the via structure 170. The pad structure 260 may include a seed layer pattern 225, a second conductive layer pattern 240 and a third conductive layer pattern 250 sequentially stacked, and the seed layer pattern 225 may contact at least a portion of the first conductive layer pattern 160, and be electrically connected thereto. The seed layer pattern 225 and the second and third conductive layer patterns 240 and 250 may include a metal, e.g., cooper (Cu), nickel (Ni), or gold (Au).

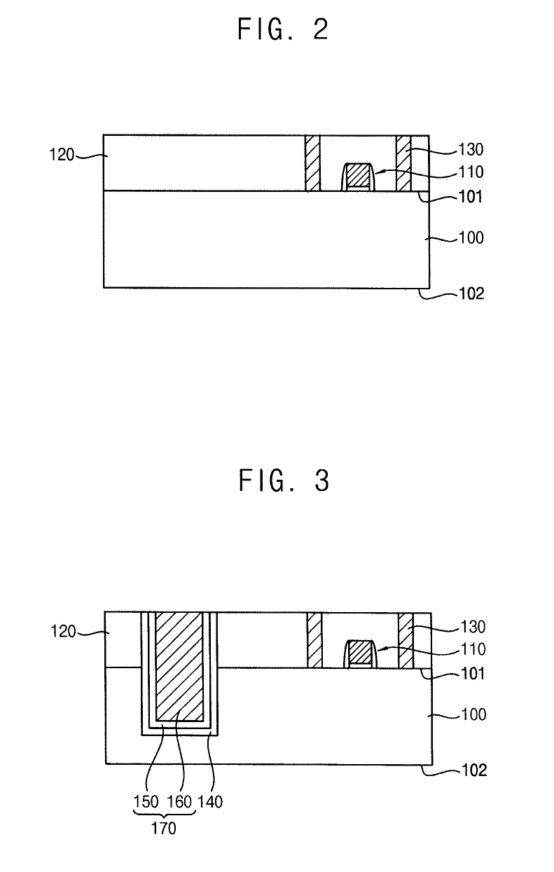

FIGS. 2 to 12 illustrate cross-sectional views depicting stages of a method of manufacturing a semiconductor device in accordance with example embodiments.

Referring to FIG. 2, a circuit pattern 110 and a first insulating interlayer 120 covering the circuit pattern 110 may be formed on a first surface 101 of a substrate 100.

The substrate 100 may be, e.g., a silicon substrate, a germanium substrate, a silicon-germanium substrate, a silicon-on-insulator (SOI) substrate, or a germanium-on-insulator (GOI) substrate.

The circuit pattern 110 may include, e.g., a transistor or a diode. A transistor is shown as the circuit pattern 110 in FIG. 2. A gate structure including a gate insulating layer pattern and a gate electrode may be formed on the first surface 101 of the substrate 100, an impurity region (not shown) may be formed at a portion of the first surface 101 of the substrate 100 adjacent to the gate structure.

The first insulating interlayer 120 may be formed by a chemical vapor deposition (CVD) process, and may be formed to include an oxide, e.g., borophosphosilicate glass (BPSG), undoped silicate glass (USG), or spin on glass (SOG).

Thereafter, the first insulating interlayer 120 may be etched to form a contact hole exposing a portion of the first surface 101 of the substrate 100, and the contact hole may be filled using a conductive material to form a contact plug 130. Accordingly, the contact plug 130 may be formed through the first insulating interlayer 120 to contact the impurity region, and the contact plug 130 and the circuit pattern 110 may be electrically connected to each other. The conductive material may include a metal and/or polysilicon doped with impurities.

Referring to FIG. 3, a hard mask (not shown) may be formed on the first insulating interlayer 120 and the contact plug 130, and the first insulating interlayer 120 and the substrate 100 may be removed partially using the hard mask as an etching mask to form a recess. Thereafter, the hard mask may be removed, and a via structure 170 filling the recess may be formed. Accordingly, the via structure 170 may be formed through the first insulating interlayer 120 and a portion of the substrate 100.

The via structure 170 may be formed by forming an insulating layer on an inner wall of the recess, the first insulating interlayer 120 and the contact plug 130, forming a barrier layer on the insulating layer, forming a first conductive layer on the barrier layer to fill a remaining portion of the recess, and planarizing the insulating layer, the barrier layer and the first conductive layer until a top surface of the first insulating interlayer 120 may be exposed. The via structure 170 including a first conductive layer pattern 160 and a barrier layer pattern 150, and an insulating layer pattern 140 surrounding a sidewall and a bottom surface of the via structure 170 may be formed in the recess.

The first conductive layer pattern 160 may be formed by an electrolytic plating process, and may be formed to include a metal, e.g., cooper (Cu) or tungsten (W). The barrier layer pattern 150 may be formed to include a metal or a metal nitride, e.g., tantalum (Ta), tantalum nitride (TaN), titanium (Ti), titanium nitride (TiN), ruthenium (Ru), cobalt (Co), nickel (Ni), nickel boride (NiB), or tungsten nitride (WN). The insulating layer pattern 140 may be formed to include an insulating material, e.g., silicon oxide or silicon nitride.

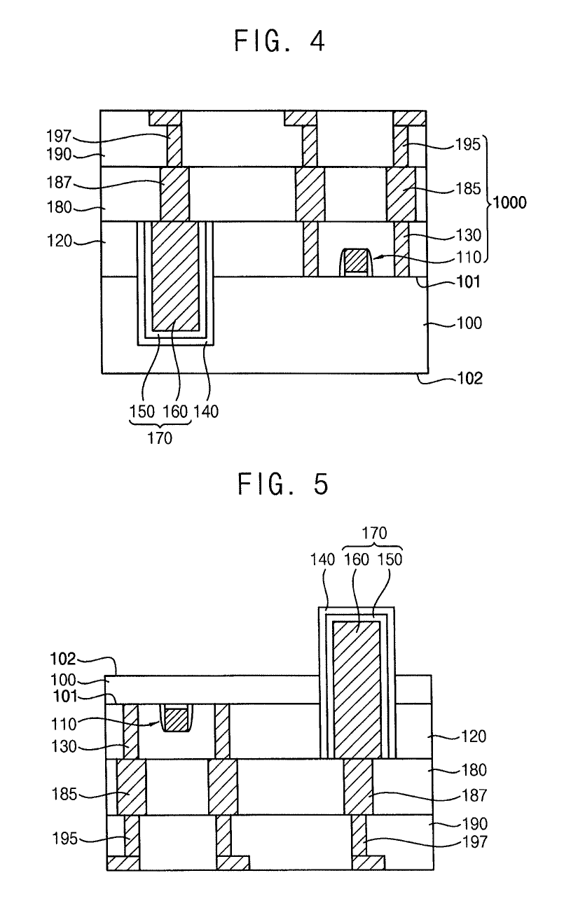

Referring to FIG. 4, a back end of line (BEOL) process may be performed. A second insulating interlayer 180 and first and second wirings 185 and 187 through the second insulating interlayer 180 may be formed on the first insulating interlayer 120, and the third insulating interlayer 190 and third and fourth wirings 195 and 197 through the third insulating interlayer 190 may be formed on the second insulating interlayer 180.

In example embodiments, the first and second wirings 185 and 187 may be formed by forming a first photoresist pattern (not shown) on the second insulating interlayer 180, etching the second insulating interlayer 180 using the first photoresist pattern as an etching mask to form first openings exposing at least a portion of the first conductive layer pattern 160 and a portion of a top surface of the contact plug 130, and filling the first openings by an electrolytic plating process. Accordingly, the first and second wirings 185 and 187 may contact the contact plug 130 and the first conductive layer pattern 160 of the via structure 170, respectively, and be electrically connected to the circuit pattern 110.

In example embodiments, the third and fourth wirings 195 and 197 may be formed by forming a second photoresist pattern (not shown) on the third insulating interlayer 190, etching the third insulating interlayer 190 using the second photoresist pattern as an etching mask to form second openings exposing at least portions of top surfaces of the first and second wirings 185 and 187, and filling the second openings by an electrolytic plating process. Accordingly, the third and fourth wirings 195 and 197 may contact the first and second wirings 185 and 187, respectively, and be electrically connected thereto.

The wirings 185 and 195, the contact plug 130 and the circuit pattern 110 may be electrically connected to each other, and the wirings 187 and 197 and the via structure 170 may be electrically connected to each other.

The wirings 185, 187, 195 and 197 may be formed to include a metal, e.g., cooper (Cu) or tungsten (W). The second and third insulating interlayers 180 and 190 may be formed to include an insulating material, e.g., silicon oxide or silicon nitride.

In FIG. 4, the second and third insulating interlayers 180 and 190 and the first to fourth wirings 185, 187, 185 and 197 are shown; however, more insulating interlayers and more wirings may be further formed.

Referring to FIG. 5, the substrate 100 may be turned over by an angle of about 180°, and the substrate 100 may be partially removed to expose a portion of the via structure 170.

In example embodiments, the substrate 100 may be partially removed by performing an etch back process on a second surface 102 of the substrate 100 on which it may not be necessary to form the circuit pattern 110.

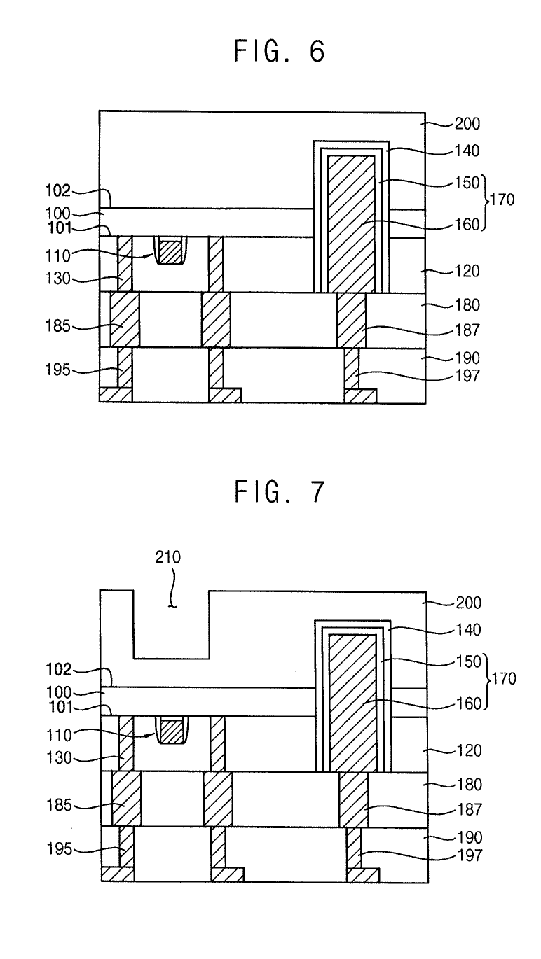

Referring to FIG. 6, a protecting layer 200 covering the exposed portion of the via structure 170 may be formed on the second surface 102 of the substrate 100 and include a photosensitive organic insulating material.

The photosensitive organic insulating material may be dissolved in a solvent to form a compound, the compound may be coated on the second surface 102 of the substrate 100 by, e.g., spin on coating, to form a preliminary protecting layer, and the substrate 100, on which the preliminary protecting layer is formed, may be soft-baked to form the protecting layer 200.

The compound may include a thermosetting organic polymer and a photosensitive material. The thermosetting organic polymer may be a thermosetting resin having an insulating characteristic, e.g., polyimide, novolac, polybenzoxazole, benzocyclobutene, silicon polymer, epoxy polymer or acrylate polymer. The photosensitive material may be a positive photosensitive material.

The compound may further include a cross linking agent and a curing catalyst.

The cross linking agent may cross link the thermosetting organic polymer, and may include, e.g., formalin, formalin-alcohol, melamine resin, urea resin, a phenolic compound including at least two methylols or at least two alkoxymethylols, and/or an epoxy compound including at least two epoxy functional groups. The curing catalyst may cause a curing reaction of the thermosetting organic polymer, and may include, e.g., acid anhydride.

In example embodiments, the compound may further include a PAG, which may be any compound generating acid by light.

The solvent may include an organic solvent.

Referring to FIG. 7, a trench 210 may be formed at an upper portion of the protecting layer 200.

The trench 210 may be formed by irradiating a light on a portion of the protecting layer 200 that does not overlap the via structure 170, using an exposure mask (not shown), and developing the protecting layer 200 divided into an exposed portion and unexposed portion by the light. The protecting layer 200 may be formed to include a positive photosensitive material, and the exposed portion of the protecting layer 200 may be dissolved during the developing process. In example embodiments, the light may be an i-line light.

The protecting layer 200 may have a photosensitive characteristic, and it may not be necessary to form an additional photoresist pattern form the trench 210.

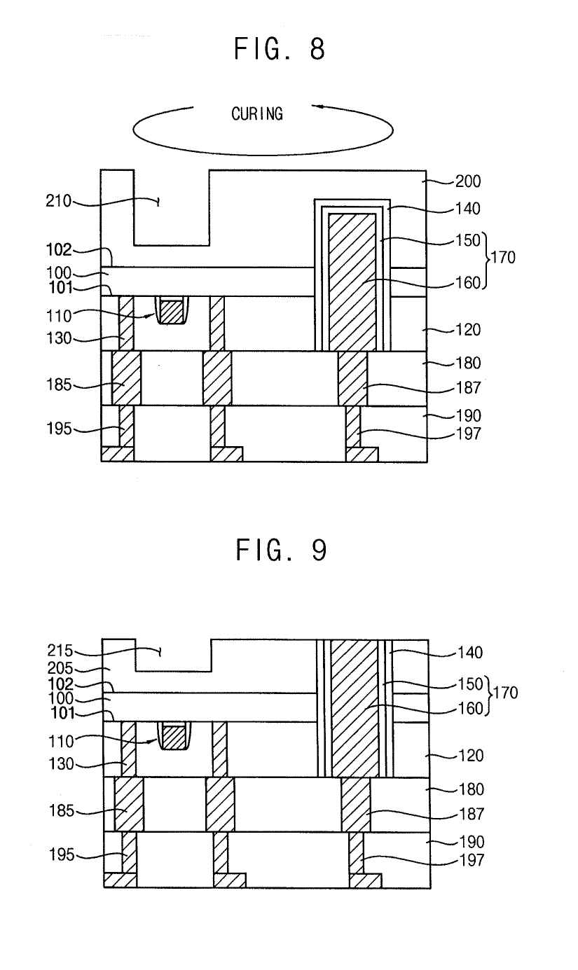

Referring to FIG. 8, the substrate 100, on which the protecting layer 200 is formed, may be heated to cure the protecting layer 200.

In example embodiments, the protecting layer 200 may be cured at a temperature of equal to or greater than about 100° C. However, the temperature may be changed in accordance with a thermosetting organic polymer of the compound.

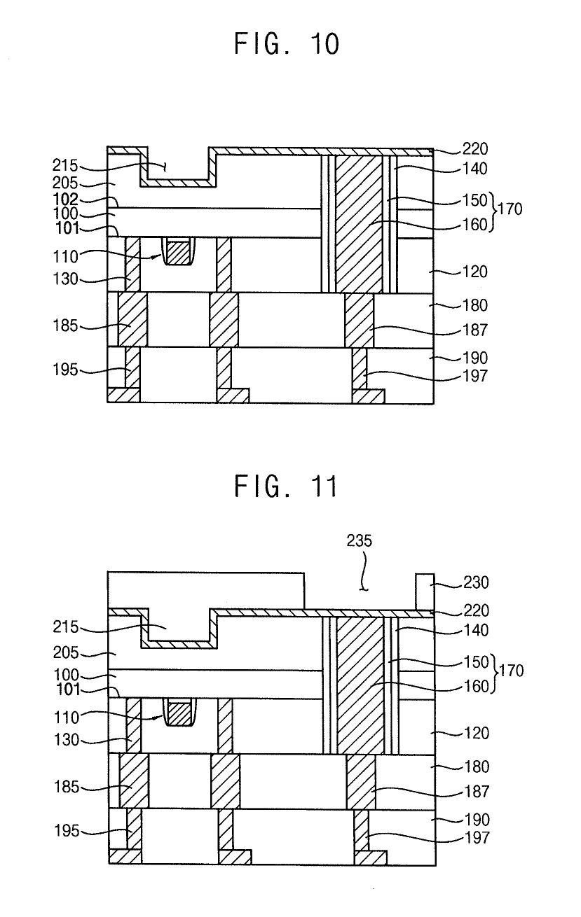

Referring to FIG. 9, the cured protecting layer 200 may be planarized until the first conductive layer pattern 160 of the via structure 170 may be exposed. By the planarizing process, a upper portion of the trench 210 may be removed, while a lower portion of the trench 210 may remain, and an alignment pattern 215 may be formed which may be used for manufacturing a stacked semiconductor device and/or a package structure including the same.

In example embodiments, the planarizing process may be performed by a chemical mechanical polishing (CMP) process or a chemical enhanced polishing (CEP) process. A CEP process is performed, and the planarizing process may be performed multiple times in accordance with an etch selectivity among the protecting layer 200, the insulating layer pattern 140, barrier layer pattern 150 and a first conductive layer pattern 160. In example embodiments, a first planarizing process may be performed until the barrier layer pattern 150 may be exposed, and a second planarizing process may be performed until the first conductive layer pattern 160.

Referring to FIG. 10, a seed layer 220 may be formed on the exposed portion of via structure 170 and the planarized protecting layer 205. Accordingly, the seed layer 200 may be formed to contact the first conductive layer pattern 160 of the via structure 170.

The seed layer 200 may be formed by a physical vapor deposition (PVD) process, and may be formed to include a metal, e.g., cooper (Cu).

In example embodiments, prior to forming the seed layer 200, a barrier layer (not shown) may be further formed on the exposed portion of via structure 170 and the planarized protecting layer 205. The barrier layer may be formed to include a metal and/or a metal nitride, e.g., titanium (Ti), tantalum (Ta), titanium nitride (TiN), or tantalum nitride (TaN).

Referring to FIG. 11, a third photoresist pattern 230 may be formed on the seed layer 200.

The third photoresist pattern 230 may have a third opening 235 exposing a portion of the seed layer overlapping the via structure 170. In example embodiments, a width of the third opening 235 may be wider than that of the via structure 170 in a top view.

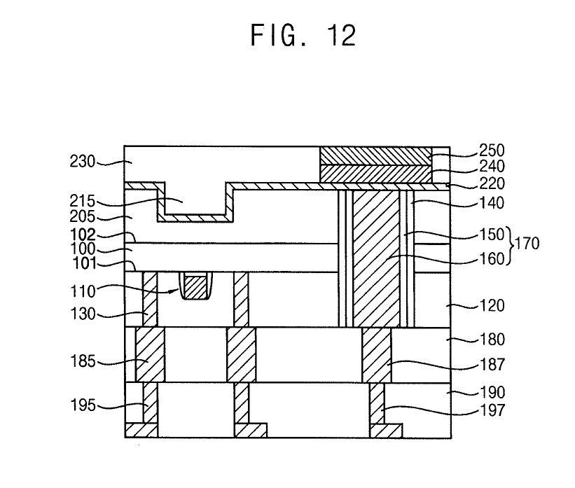

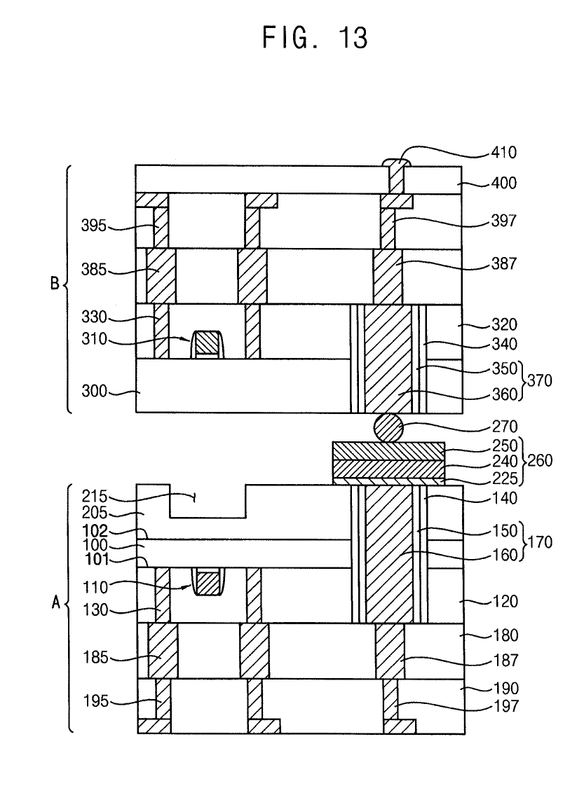

Referring to FIG. 12, second and third conductive layer patterns 240 and 250 may be formed to fill the third opening 235.

In example embodiments, the second conductive layer filling the third opening 235 may be formed on the seed layer 220 and the third photoresist pattern 230 by a plating process, and an upper portion of the second conductive layer may be removed to form the second conductive layer pattern 240. Accordingly, the second conductive layer pattern 240 may be formed to fill a portion of the third opening 235.

In example embodiments, the third conductive layer filling a remaining portion of the third opening 235 may be formed on the second conductive layer pattern 240 and the third photoresist pattern 230 by a plating process, and the third conductive layer may be planarized until a top surface of the third photoresist pattern 230 may be exposed. Accordingly, the third conductive layer 250 may be formed on the second conductive layer pattern 240 to fill the remaining portion of the third opening 235.

During the plating process, the seed layer 220 may serve as an electrode for formation of the second conductive layer pattern 240 and/or formation of the third conductive layer pattern 250. The second and third conductive layer patterns 240 and 250 may be formed to include a metal, e.g., nickel (Ni) and gold (Au), respectively.

Referring to FIG. 1 again, the third photoresist pattern 230 may be removed, and an exposed portion of the seed layer 220 may be removed to form a seed layer pattern 225. The seed layer pattern 225 and the second and third conductive layer patterns 240 and 250 may be defined as a pad structure 260.

The third photoresist pattern 230 may be removed by, e.g., a wet etching process.

The exposed portion of the seed layer 200 may be removed by, e.g., a dry etching process using the second and third conductive layer patterns 240 and 250 as an etching mask.

In example embodiments, the pad structure 260 may be formed using the third opening 235, and the pad structure 260 may be formed to have a width wider than that of the via structure 170 in a top view. In this case, a pressure applied to the pad structure 260 for manufacturing a stacked semiconductor device and/or a package structure including the same may be reduced.

As described above, the protecting layer 205 may be formed to include a photosensitive organic insulating material, and expensive equipment may not be needed for formation of the protecting layer 205, and further, the protecting layer 205 may be formed as a single layer. In addition, the protecting layer 205 may have a photosensitive characteristic, and it may not be necessary to further form an additional photoresist pattern on the protecting layer 205 to form the alignment pattern 215.

Therefore, steps for forming the pad structure 260 may be reduced or minimized, and the process may be simplified and efficiency of the process may be improved.

FIG. 13 illustrates a cross-sectional view depicting a stage of a method of manufacturing a stacked semiconductor device in accordance with example embodiments. This method may include processes substantially the same as or similar to those illustrated with reference to FIGS. 1 to 12, and thus like reference numerals refer to like elements, and detailed explanations thereabout may be omitted herein.

Referring to FIG. 13, processes substantially the same as or similar to those illustrated with reference to FIGS. 1 to 12 may be performed, and a first semiconductor device A may be formed to include a first circuit pattern 110, a first via structure 170, a first protecting layer 205, a pad structure 260 and wirings 185, 187, 195 and 197. Thereafter, a conductive bump 270 may be formed on the pad structure 260 of the first semiconductor device A, and a second semiconductor device B may be stacked on the first semiconductor device A using the conductive bump 270.

The conductive bump 270 may be formed to contact a third conductive layer pattern 250 of the pad structure 260, and may be formed to include, e.g., a metal.

The second semiconductor device B may be a semiconductor device substantially the same as or different from the first semiconductor device A. The second semiconductor device B may include a second circuit 310, a second contact plug 330 and fifth and seventh wirings 385 and 395 which may be electrically connected to each other, and include a second via structure 370 and sixth and eighth wirings 387 and 397 which may be electrically connected to each other. A fourth conductive layer pattern 360 of the second via structure 370 may contact the conductive bump 270, and the second semiconductor device B may be stacked on the first semiconductor device A to be electrically connected thereto.

In example embodiments, the second semiconductor device B may further include a second protecting layer 400 and a connection member 410 on top surfaces of the wirings 395 and 397. In this case, the connection member 410 be electrically connected to a printed circuit board (PCB) via a bump or a wiring bonding, or electrically connected to other semiconductor devices. Stacking the second semiconductor B on the first semiconductor device A is shown in FIG. 13; however, more semiconductor devices may be further stacked.

By way of summation and review, when a plurality of semiconductor chips are stacked to form a package structure, a via structure may be formed through a portion of a substrate on which circuit patterns are formed, and a surface of the substrate, on which the circuit patterns are not formed, may be partially removed to expose a portion of the via structure. Thereafter, a protecting layer having an alignment pattern may be formed to surround a sidewall of the exposed portion of the via structure, and a pad structure may be formed on the protecting layer to contact the via structure, and thus each of the semiconductor chips may be electrically connected each other.

However, when the pad structure is formed, additional processes, e.g., forming a protecting layer and/or forming an alignment pattern, may be performed, and a cost for manufacturing the semiconductor device may be increased and productivity may be reduced. For example, the protecting layer may be formed to include silicon oxide by a chemical vapor deposition (CVD) process, and thus expensive equipment may be needed for formation of the protecting layer, and a barrier layer may be further formed between the protecting layer and the substrate. Moreover, an additional mask may be further formed on the protecting layer, and the protecting layer may be patterned using the additional mask as an etching mask to form an alignment pattern.

The presently disclosed protecting layer may be formed using a compound including a thermosetting organic polymer and a photosensitive material. The protecting layer may be formed easily by coating the compound on the substrate, and it may not be necessary to further form the barrier layer. In addition, the protecting layer may have a photosensitive characteristic, and it may not be necessary to further form a mask on the protecting layer to form the alignment pattern.

Example embodiments may provide a method of manufacturing a semiconductor device and a semiconductor device having increased productivity.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of manufacturing a semiconductor device, the method comprising:
forming a via structure through a portion of a substrate;
partially removing the substrate to expose a portion of the via structure;
forming a protecting layer on the substrate to cover the portion of the via structure exposed by partially removing the substrate, the protecting layer including a photosensitive organic insulating material;
curing the protecting layer to form a cured protecting layer;
planarizing the cured protecting layer until a part of the via structure is exposed; and
forming a pad structure to contact the part of the via structure exposed by planarizing the cured protecting layer.

2. The method as claimed in claim 1, wherein forming the protecting layer on the substrate includes:
coating a compound including a thermosetting organic polymer and a photosensitive material on the substrate to form a preliminary protecting layer; and
soft-baking the substrate on which the preliminary protecting layer is formed.

3. The method as claimed in claim 2, wherein the preliminary protecting layer further includes a cross linking agent and a curing catalyst.

4. The method as claimed in claim 1, further comprising, prior to curing the protecting layer, forming a trench for forming an alignment pattern at an upper portion of the protecting layer.

5. The method as claimed in claim 4, wherein forming the trench includes:
irradiating a light on a portion of the protecting layer using an exposure mask; and
developing the portion of the protecting layer irradiated with the light.

6. The method as claimed in claim 1, wherein forming the via structure includes:
partially removing the substrate to form a recess;
forming an insulating layer on an inner wall of the recess and on the substrate;
forming a barrier layer on the insulating layer, the forming of the insulating layer and the barrier layer partially filling the recess;
forming a first conductive layer on the barrier layer to fill a remaining portion of the recess; and
planarizing the first conductive layer, the barrier layer and the insulating layer until a top surface of the substrate is exposed to form an insulating layer pattern, a barrier layer pattern and a first conductive layer pattern sequentially stacked in the recess.

7. The method as claimed in claim 6, wherein the cured protecting layer is planarized until the first conductive layer pattern is exposed.

8. The method as claimed in claim 1, further comprising, prior to forming the pad structure:
forming a seed layer on the portion of the via structure exposed by planarizing the cured protecting layer and on the protecting layer; and
forming a photoresist pattern on the seed layer, the photoresist patter having an opening exposing a portion of the seed layer overlapping the via structure,
wherein forming the pad structure includes:
forming a second conductive layer to fill the opening;
removing the photoresist pattern to expose a part of the seed layer; and
removing the part of the seed layer exposed by removing the photoresist pattern.

9. The method as claimed in claim 8, wherein forming the second conductive layer includes performing a plating process.

10. The method as claimed in claim 1, further comprising, prior to forming the via structure:
forming a circuit pattern on the substrate; and
forming an insulating interlayer on the substrate to cover the circuit pattern,
wherein the via structure is formed through the insulating interlayer.

11. The method as claimed in claim 1, further comprising, after forming the pad structure, stacking a semiconductor chip on the pad structure to be electrically connected thereto.

12. A semiconductor device, comprising:
a via structure in a substrate, a portion of the via structure being exposed to an outside of the substrate;
a protecting layer surrounding a sidewall of the portion of the via structure exposed to the outside of the substrate, the protecting layer including a thermosetting organic polymer and a photosensitive material; and
a pad structure contacting a top surface of the portion of the via structure exposed to the outside of the substrate.

13. The semiconductor device as claimed in claim 12, wherein the protecting layer includes an alignment pattern.

14. The semiconductor device as claimed in claim 12, wherein the via structure includes a first conductive layer pattern and a barrier layer pattern surrounding a sidewall of the first conductive layer pattern, and wherein the pad structure contacts at least a portion of the first conductive layer pattern.

15. The semiconductor device as claimed in claim 12, wherein the pad structure includes a seed layer pattern and a second conductive layer pattern sequentially stacked.

16. A method of manufacturing a semiconductor device, comprising:
removing a portion of a substrate to expose a portion of a via structure in the substrate; and
coating a protecting layer directly on the substrate to cover the portion of the via structure exposed by removing a portion the substrate, the protecting layer including a thermosetting organic polymer and a photosensitive material.

17. The method as claimed in claim 16, further comprising forming an alignment pattern in the protecting layer without forming a photoresist pattern on the protecting layer.

18. The method as claimed in claim 17, wherein forming the alignment pattern in the protecting layer includes:
irradiating a light on a portion of the protecting layer that does not overlap the via structure; and
developing the protecting layer such that the portion of the protecting layer irradiated by the light dissolves.

19. The method as claimed in claim 16, further comprising:
curing the protecting layer to form a cured protecting layer;
planarizing the cured protecting layer to expose a part of the via structure; and
forming a pad structure to contact the part of the via structure exposed by planarizing the cured protecting layer,
wherein the protecting layer is formed as a single layer.

20. The method as claimed in claim 16, wherein:
the photosensitive material is dissolved in a solvent to form a compound, which is coated on the substrate by spin on coating; and
the thermosetting organic polymer is selected from polyimide, novolac, polybenzoxazole, benzocyclobutene, silicon polymer, epoxy polymer, or acrylate polymer.
